(19) United States
(12) Patent Application Publication
(10) Pub. No.: US 2005/0045805 A1
(43) Pub. Date: Mar. 3, 2005

(54) Solid-state image sensor and a manufacturing method thereof

(76) Inventors: Hiroshi Sakoh, Kyotanabe-shi (JP); Michiyo Ichikawa, Kyoto-shi (JP); Yoshiaki Nishi, Kyoto-shi (JP)

Correspondence Address: WENDEROTH, LIND & PONACK, L.L.P., 2033 K STREET N. W., SUITE 800, WASHINGTON, DC, 20006-1021, US

(21) Appl. No.: 10/927,278

(22) Filed: Aug. 27, 2004

(30) Foreign Application Priority Data
Aug. 29, 2003 (JP) 2003-307848

(51) Int. Cl. H01L 27/00

(52) U.S. Cl. 250/208.1

(57) ABSTRACT

The solid-state image-sensor in the present invention is made by stacking a flattened transparent insulating film 2 made out of material such as boron phosphate silicate glass (BPSG), a convex-topped high refractive index (n>1.8) in-layer lens 3, a color filter layer 5 made out of a color resist containing a dye or pigment, a transparent film 6 made out of an acrylic transparent resin, and a micro-lens (also known as a top lens) 7, on top of a photodiode 1 formed on a silicon semiconductor substrate 10, where the color filter layer 5 is directly applied on the in-layer lens 3.

### BACKGROUND OF THE INVENTION

(1) Field of the Invention

The present invention relates to a solid-state image sensor including in-layer lenses and color filters for a plurality of light-receiving elements formed on a semiconductor substrate, and the manufacturing method thereof.

(2) Description of the Related Art

In recent years, the miniaturization of the cells of solid-state image sensors is progressing, and high-sensitivity technology is becoming a necessity as light-receiving elements become smaller. Consequentially, in a solid-state image sensor, the improvement of reception sensitivity is sought through the formation of micro-lenses above each light-receiving element and light-collection of incident light in the light-receiving elements.

FIG. 1 is a diagram showing a cross-section of an existing solid-state image sensor. The cross-section for two photodiodes is illustrated in the diagram. As shown in the diagram, a photodiode 1 which is a light-receiving element that performs photoelectric conversion, an insulating film 2, an in-layer lens 3, an in-layer lens flat film 4, a color filter layer 5, a transparent film 6, and a micro-lens 7, are formed on a silicon semiconductor substrate 10, in the solid-state image sensor. The size of a cell containing the photodiode 1 is miniaturized, and for example, a convex, high refractory rate in-layer lens 3 with a refractory rate (n>1.8) is formed in a cell size which is equal to or less than 3 μm in length and width.

FIG. 2(a) to (d) is a diagram illustrating cross-sections of the existing solid-state image sensor, in manufacturing sequence. More specifically, in an existing construction method, a photodiode 1, an insulating film 2, and an in-layer lens 3 are first formed on a semiconductor substrate 10 (FIG. 2(a)). Subsequently, a transparent film 4 made of acrylic, or the like is applied (FIG. 2(b)), and the transparent film 4 is removed up to the vicinity of the top of the in-layer lens 3 by etching back (FIG. 2(c)), creating a completely flattened surface. Alternatively, this flattening process forms the transparent film 4 by the application, exposure, development and flow processing a flowable transparent film resist as the transparent film 4. In addition, color filter layers 5 are formed by being applied, exposed, and developed for each color (FIG. 2(d)).

Furthermore, official publication of Japanese Laid-Open Patent Application No. 2001-44406, and so on, discloses a solid-state image sensor having a light-collecting lens 20 formed virtually on top a light-receiving unit, and a flattening film 17 and a color filter 18 formed on a concave flattening film 16, as illustrated in FIG. 3.

According to the existing technology in FIG. 1 and FIG. 3, in order to let in as much incident light onto the photodiodes as possible, an in-layer lens (light-collecting lens) with a high refractive index is formed, and the improvement of sensitivity is promoted.

However, there is the problem that release sensitivity improvement and incidence angle widening are difficult for the solid-state image sensors in the aforementioned existing technology.

To be specific, the problem exists in which release sensitivity improvement and incidence angle widening become difficult due to the attenuation, reflection, and dispersion of incident light as the distance between the photodiode 1 and the micro-lens 7 in FIG. 1, and the distance between the light-receiving unit and the color filter in FIG. 3, become greater.

Furthermore, as the color filter and light-receiving unit (photodiode) distance is great, there is also the problem that color mixing from adjacent color filters is more likely to occur.

### SUMMARY OF THE INVENTION

The present invention has as an objective to provide a solid-state image sensor that easily prevents color mixing, improves release sensitivity and promotes incidence angle widening as well, and a manufacturing method thereof.

In order to resolve the aforementioned issues, the solid-state image sensor in the present invention is a solid-state image sensor comprising: an in-layer lens for each of a plurality of light-receiving elements formed on a semiconductor substrate; and a color filter for each of the plurality of light-receiving elements, wherein the color filter is placed directly on the in-layer lens.

According to this structure, as the color filter is directly applied so as to coat the inner-layer lens, the distance between the existing color filter and the photodiode (FIG. 3), and the distance between the photodiode and the micro-lens (FIG. 1) is shortened, reducing the attenuation, dispersion, and reflection of incident light, and enabling the realization of release sensitivity improvement as well as incidence angle widening. Additionally, color mixing from adjacent color filters can be reduced.

Here, it is possible to have a structure where the solid-state image sensor further comprises a transparent thin-film between the color filter and the in-layer lens, formed along a convex surface of the in-layer lens (see FIG. 6).

Furthermore, it is possible to have a structure where the solid-state image sensor further comprises an inter-lens flat film that forms a flat surface at a position which is lower than an upper portion of the in-layer lens by covering areas between the in-layer lenses and portions of a convex surface of the in-layer lens that are lower than said position (see FIG. 8).

According to this structure, spectral adjustment can be carried out easily as a result of the film thickness of the inter-lens flat film.

Here, it is possible to have a structure where the color filter is placed only above the in-layer lens (see FIG. 12).

Here, it is possible to have a structure where an upper surface of the color filter is convex (see FIG. 12).

Furthermore, the manufacturing method of the solid-state image sensor in the present invention is a manufacturing method for a solid-state image sensor including an in-layer lens and a color filter for each of a plurality of light-receiving elements formed on a semiconductor substrate, the method comprising: a first step of applying a resist for a color filter for a first color, on the semiconductor substrate after the in-layer lens is formed; a second step of exposing the resist using a mask pattern for the color filter for the first color; a third step of developing the resist so as to leave the color filter for the first color in place, after the exposure; and a fourth step of performing said application, exposure, and development for color filters for colors aside from the first color.

According to this structure, as shown in FIG. 4, as the color filter is directly applied so as to coat the inner-layer lens, the distance between the existing color filter and the photodiode (FIG. 3), and the distance between the photodiode and the micro-lens (FIG. 1) is shortened, enabling the realization of release sensitivity improvement as well as incidence angle widening. Additionally, color mixing from adjacent color filters can be reduced.

It is possible to have a structure where the manufacturing method comprises a step of forming a transparent thin-film along a convex surface of the in-layer lens prior to the first step, wherein the resist is formed above the in-layer lens by being applied on the transparent thin-film, in the first and fourth steps. With this, a solid-state image sensor as shown in FIG. 6 is manufactured.

It is possible to have a structure where the manufacturing method further comprises the following steps which are performed prior to the first step: a step of applying a transparent film on the in-layer lenses and in areas between the in-layer lenses; and a step of removing, by etch back, the applied transparent film up to a position that is lower than a height of the in-layer lens. With this, a solid-state image sensor as shown in FIG. 8 is manufactured.

It is possible to have a structure where the manufacturing method further comprises the following steps which are performed prior to the first step: a step of applying a transparent film that can be subjected to patterning, on the in-layer lenses and in areas between the in-layer lenses; a step of exposing the applied transparent film, using a mask for leaving the transparent film in place in the areas between the in-layer lenses; a developing step of developing, after exposing, so as to leave the applied transparent film in place only between the in-layer lenses; and a step of flattening the transparent film so as to cover areas between the in-layer lenses and a surface of a rim of the in-layer lenses through flow processing of the transparent film left in place by developing. With this, a solid-state image sensor as shown in FIG. 8 is manufactured.

It is possible to have a structure where the manufacturing method further comprises the following steps which are performed after the fourth step: a step of applying a flowable resist on the color filter; a step of exposing the flowable resist using a mask for leaving the flowable resist in place on the in-layer lens, a step of leaving the flowable resist in place on the in-layer lens by development, and forming the flowable resist that is left in place, into a convex by flow processing; and a step of forming the color filter into a convex on the in-layer lens by etching back the flowable resist formed into a convex. With this, a solid-state image sensor as shown in FIG. 12 is manufactured.

According to the manufacturing method mentioned above, release sensitivity improvement and incidence angle widening can be realized by a structure in which the color filter is directly applied on the in-layer lens (or not completely flattening the area above the in-layer lens with the transparent film).

As explained thus far, according to the solid-state image sensor as well as the manufacturing method in the present invention, flat-filming of the solid-state image sensor, in other words, shortening of the distance from the top lens (micro-lens 7) to the light-receiving area, in comparison to the existing solid-state image sensor, is possible, reducing the attenuation, dispersion, and reflection of incident light, and enabling the realization of release sensitivity improvement as well as incidence angle widening.

In addition, color mixing from adjacent color filters can be reduced.

### FURTHER INFORMATION ABOUT TECHNICAL BACKGROUND TO THIS APPLICATION

The disclosure of Japanese Patent Application No. 2003-307848 filed on Aug. 29th, 2003, including specification, drawings and claims, is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention.

In the Drawings:

FIG. 1 is a cross-section diagram of a solid-state image sensor in the existing technology.

FIG. 2 is a diagram illustrating the manufacturing process of a solid-state image sensor in the existing technology.

FIG. 3 is diagram illustrating the cross-section of a solid-state image sensor in the existing technology.

FIG. 4 is a cross-section diagram of the solid-state image sensor in the first embodiment of the present invention.

FIG. 5 is an explanatory diagram illustrating the manufacturing process of the solid-state image sensor in the same embodiment.

FIG. 6 is a cross-section diagram of the solid-state image sensor in the second embodiment of the present invention.

FIG. 7 is a diagram illustrating the manufacturing process of the solid-state image sensor in the same embodiment.

FIG. 8 is a cross-section diagram of the solid-state image sensor in the third embodiment of the present invention.

FIG. 9 is a diagram illustrating the manufacturing process of the solid-state image sensor in the same embodiment.

FIG. 10 is a diagram illustrating the manufacturing process (first-half) of the solid-state image sensor in the same embodiment.

FIG. 11 is a diagram illustrating the manufacturing process (second-half) of the solid-state image sensor in the same embodiment.

FIG. 12 is a cross-section diagram of the solid-state image sensor in the fourth embodiment of the present invention.

FIG. 13 is a diagram illustrating the manufacturing process (first-half) of the solid-state image sensor in the same embodiment.

FIG. 14 is a diagram illustrating the manufacturing process (second-half) of the solid-state image sensor in the same embodiment.

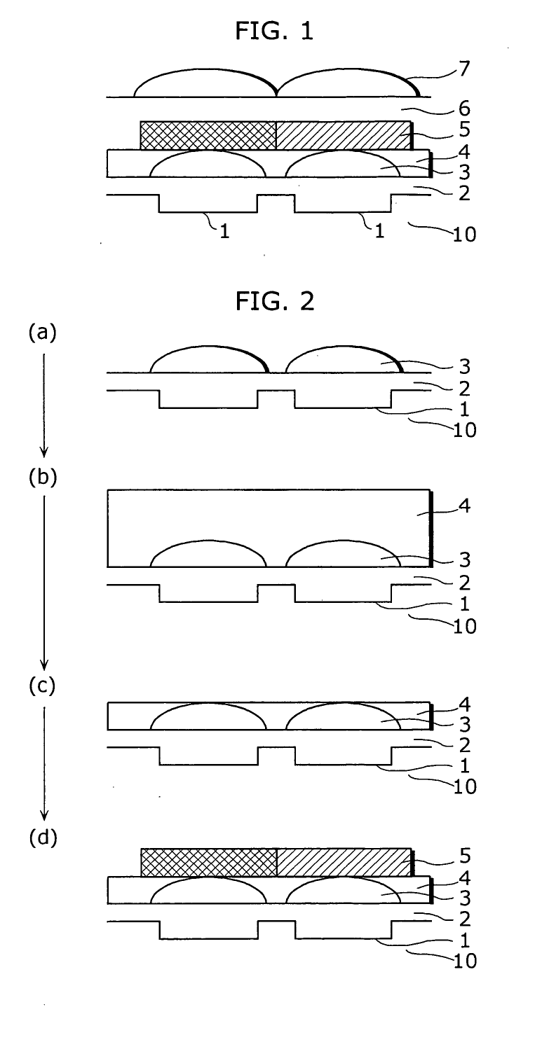

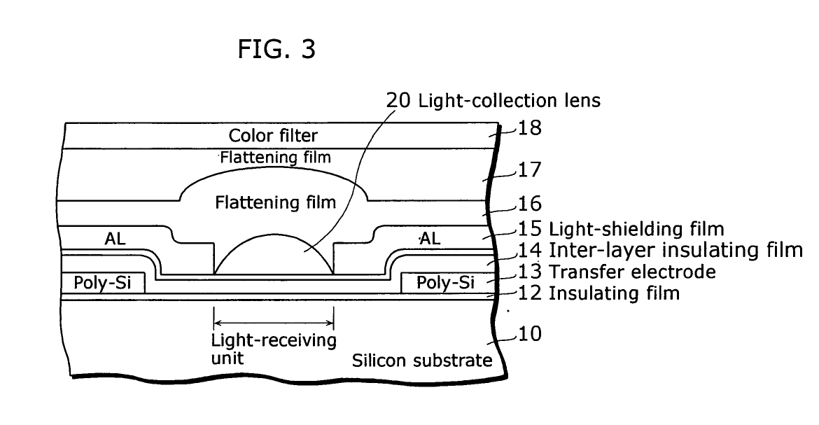

### DESCRIPTION OF THE PREFERRED EMBODIMENT(S)

(First Embodiment)

(Structure of the Solid-State Image Sensor)

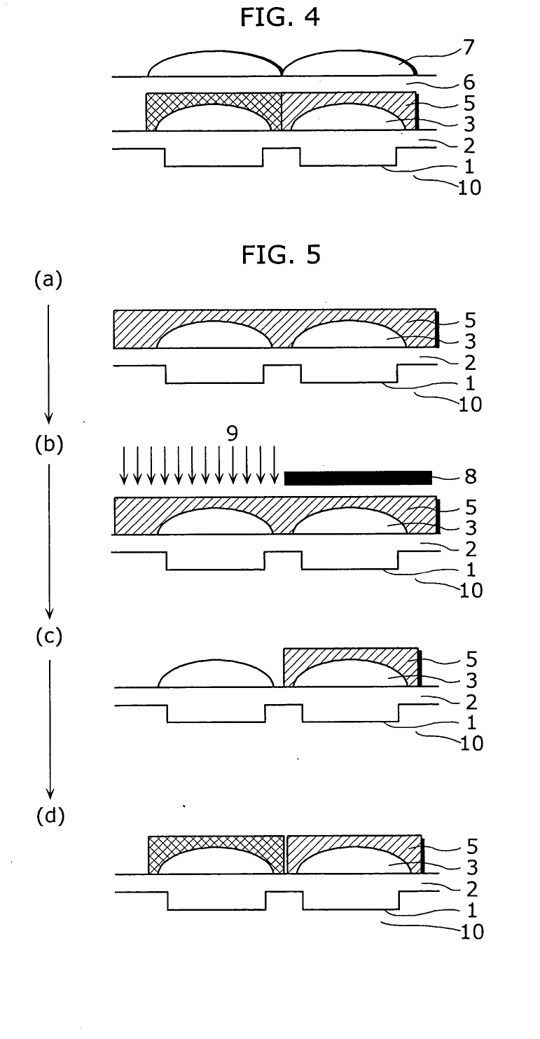

FIG. 4 is a diagram illustrating a cross-section of the solid-state image sensor in the first embodiment of the present invention. This solid-state image sensor includes light-receiving elements (photodiodes) arranged two-dimensionally. The same diagram illustrates the cross-section for two light-receiving elements.

This solid-state image sensor is made by stacking a flattened transparent insulating film 2 made out of material such as boron phosphate silicate glass (BPSG), a convex-topped high refractive index (n>1.8) in-layer lens 3, a color filter layer 5 made out of a color resist containing a dye or pigment, a transparent film 6 made out of an acrylic transparent resin, and a micro-lens (also known as a top lens) 7, above a photodiode 1 formed on a silicon semiconductor substrate 10.

The colors of the color filter layer 5 are individually determined according to the color array (e.g., Bayer Array) of the solid-state image sensor. This color filter layer 5 is placed directly on the in-layer lens 3. As such, the distance from the top lens (micro-lens 7) to the photodiode 1 can be reduced by the non-placement of a flat film between the color filter layer 5 and the in-layer lens 3. As a result, release sensitivity improvement and incidence angle widening can be realized. Stated in other words, as it is possible to reduce the distance from the top lens (micro-lens 7) in comparison with the existing solid-state image sensor, the possibility of incident light from the micro-lens 7 attenuating, dispersing and reflecting before reaching the photodiode is lowered, and light-collection rate and sensitivity are improved.

Moreover, the size of individual cells containing a single photodiode 1 is, for example, about 3 μm in length and width or less, in the solid-state image sensor in the present embodiment.

(Manufacturing Method for the Solid-State Image Sensor)

FIG. 5(a) to (d) is a diagram illustrating, in manufacturing sequence, cross-sections of the solid-state image sensor in the present embodiment shown in FIG. 4. Such manufacturing process is explained in (11) to (16) below.

(11) As shown in FIG. 5(a), 0.3 to 1.01 μm of a color filter resist 5 is applied directly on an in-layer lens 3, creating a flat surface. Here, for example, among the 3 colors RGB, the color of the color filter resist 5 is assumed to be R (red).

(12) As shown in FIG. 5(b), a resist mask 8 is placed on the applied color filter resist 5 and exposure is carried out. In the case where the color filter resist 5 is of a positive-type, for example, the resist mask 8 only masks the photodiodes corresponding to the color red, within the predetermined color array (e.g., Bayer Array). It is also possible for the negative-type.

(13) As shown in FIG. 5(c), by developing the exposed color filter resist, a red color filter layer 5 is formed on top of the in-layer lens 3 by leaving the color filter resist in place above the photodiode 1 corresponding to the color red, and removing everything else.

(14) As in (11) to (13) mentioned above, a blue color filter layer 5, and a green color filter layer 5 are respectively formed by patterning. With this, the color filter layer 5 for each color is formed in respective positions according to the color array.

(15) As shown in FIG. 4, a transparent film 6 made out of an acrylic transparent resin, for example, is formed on the color filter layer 5. This transparent film 6 is formed by applying an acrylic transparent resin several times and then flattening the upper surface by etching back. Moreover, in place of an acrylic transparent resin, it is also possible to form a transparent film 6 from a phenolic resin by using commonly known photolithography technology to flatten a phenolic resin containing a photosensitizing agent.

(16) Next, a micro-lens 7 is formed on the transparent film 6. For example, the micro-lens 7 is formed through commonly known photolithography technology in which a photosensitizing agent is blended in a phenolic transparent resin, and in addition, it is formed in such a way that transmissivity is increased by ultra-violet ray irradiation. As a result of these processes, the solid-state image sensor having the cross-section shown in FIG. 4 is formed.

As explained thus far, according to the solid-state image sensor in the present embodiment and the manufacturing method thereof, as the color filter layer 5 is applied directly on the in-layer lens 3, reduction of the distance from the light-receiving area of the photodiode 1 to the top lens (First micro-lens 7) becomes possible, and improvement of release sensitivity and incidence angle widening is made easier. In addition, as it is possible to reduce the distance of the color filter layer 5 and the light-receiving area of the photodiode 1, color mixing from an adjacent color filter layer 5 can be reduced.

(Second Embodiment)

(Structure of the Solid-State Image Sensor)

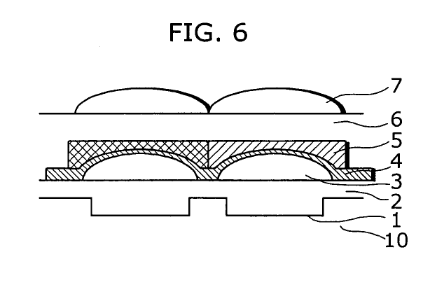

FIG. 6 is a diagram illustrating a cross-section of the solid-state image sensor in the second embodiment of the present invention. The structure of the solid state image sensor in the diagram is different, in comparison to that in FIG. 4, in that a thin-film 4 is interposed between the in-layer lens 3 and the color filter layer 5. Explanation regarding points that are the same as in FIG. 4 shall be omitted, and explanation centering on the points of difference shall be made hereinafter.

The thin-film 4 is a transparent film made out of acrylic, or the like with a refractive index of about n=1.4 to 1.6. On the surface of the in-layer lens 3, it is a thin-film of up to about 0.4 μm running along the contour of such surface. In the areas between each of the in-layer lenses, it is a thin-film of about 0.2 to 0.5 μm. With this, the manufacturing process of the color filter layer 5 is simplified. In other words, the flexible adjustment (spectral adjustment) of the film thickness of the color filter layer 5 can be simplified due to the presence of the thin-film 4 in the areas between the in-layer lenses 3.

(Manufacturing Method for the Solid-State Image Sensor)

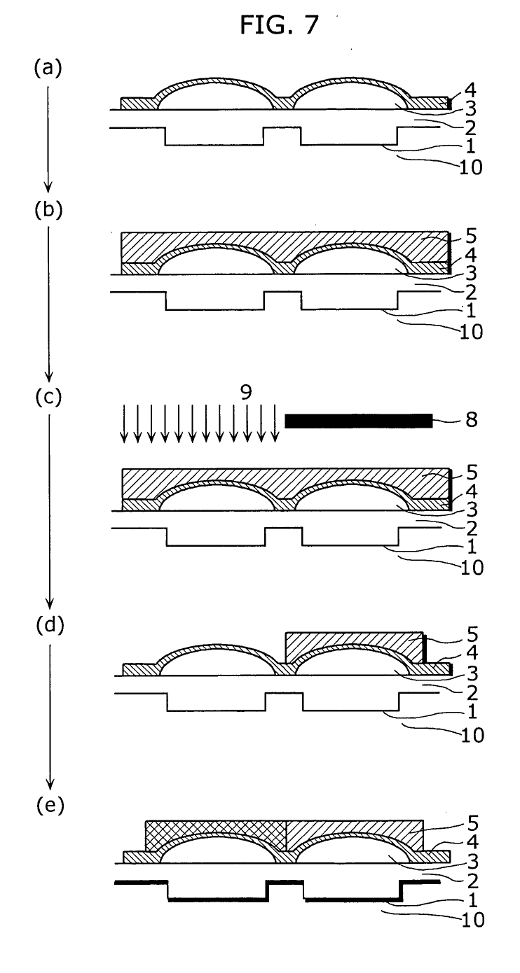

FIG. 7(a) to (e) is a diagram illustrating, in manufacturing sequence, cross-sections of the solid-state image sensor in the second embodiment shown in FIG. 6. Such manufacturing process is explained in (21) to (27) below.

(21) As shown in FIG. 7(a), one to two layers, amounting to about 0.1 to 0.5 μm, of an acrylic-like thin-film 4 with a refractive index of about 1.4 to 1.6, is applied on the in-layer lens 3. As such, the transparent film above the in-layer lens 3 is made as a thin film of up to about 0.4 μm, a nd the transparent film on the areas between each of the in-layer lenses 3 is made to about 0.2 to 0.5 μm. This thin-film 4 enables the simplification of the forming process of the color filter layer 5, in comparison to the first embodiment, as it fills in the angular areas made by the insulating film 2 and the rim of the in-layer lens 3.

(22) As shown in FIG. 7(b), 0.3 to 1.0 μm of a color filter resist 5 is applied on the transparent film 4. Here, for example, among the 3 colors RGB, the color of the color filter resist 5 is assumed to be R (red).

(23) As shown in FIG. 7(c), a resist mask 8 is placed on the applied color filter resist 5 and exposure is carried out. In the case where the color filter resist 5 is of a positive-type, for example, the resist mask 8 only masks the photodiodes corresponding to the color red, within the predetermined color array (e.g., Bayer Array). It is also possible for the negative-type.

(24) As shown in FIG. 7(d), by developing the exposed color filter resist, a red color filter layer 5 is formed on top of the thin-film 4 by leaving the color filter resist in place above the photodiode 1 corresponding to the color red and removing everything else. During that time, the color filter resist corresponding to another color is removed. As the rim of the in-layer lens 3 is not angular, residue in such areas is minimized and easy removal is made possible.

(25) As shown in FIG. 7(e), a blue color filter layer 5, and a green color filter layer 5 are respectively formed by patterning, in the same manner as in (22) to (24) mentioned above. With this, the color filter layer 5 for each color is formed in respective positions according to the color array.

(26) As shown in FIG. 6, a transparent film 6 is formed on the color filter layer 5, in the same manner as in (15) mentioned previously.

(27) In the same manner as in (16) mentioned previously, a micro-lens 7 is formed on the transparent film 6. With this, the solid-state image sensor having the cross-section shown in FIG. 6 is formed.

As explained thus far, according to the solid-state image sensor in the present embodiment and the manufacturing method thereof, in addition to such effects as the improvement of release sensitivity and the reduction of color mixing explained in the first embodiment, the color filter forming process can be carried out with ease as the color filter layer 5 is formed after the angular areas at the rim of the in-layer lens 3, above the insulating film 2, is filled-in with the thin-film 4. In other words, compared to when the thin-film 4 does not exist, spectral adjustment of the color filter layer 5 can be made easier.

Moreover, although a thin-film 4 is present on the surface of the in-layer lens 3 in FIG. 6, it is also possible not to have it on the surface of the of the top portion of the in-layer lens 3 as the same effect can also be obtained if it were present in the areas between the in-layer lenses 3.

(Third Embodiment)

(Structure of the Solid-State Image Sensor)

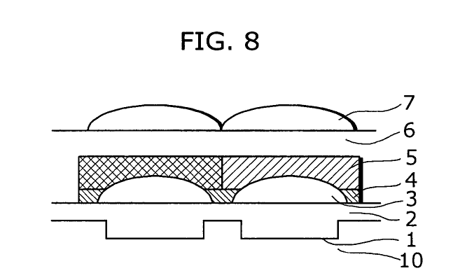

FIG. 8 is a diagram illustrating a cross-section of the solid-state image sensor in the third embodiment of the present invention. The structure of the solid state image sensor in the diagram is different, in comparison to the structure shown in FIG. 6 in the second embodiment, in that a thin-film 4 is not found on the surface of the top portion of the in-layer lens 3. Explanation regarding points that are the same as in FIG. 4 shall be omitted, and explanation centering on the points of difference shall be made hereinafter.

The thin-film 4 is formed up to a position which is lower than the height of the in-layer lens 3. It forms a flat surface from the surface area of the convex of in-layer lens that is lower than such position and the areas between each of the in-layer lenses. In other words, it forms the flat surface by filling in the rim areas of the in-layer lenses 3 and the areas between each of the in-layer lenses. As such, the thin-film 4 is the flat film which is not present on the top portion of the surface of the in-layer lenses 3, but found on the rim areas of the surface of the in-layer lenses 3 and on the areas between the in-layer lenses 3. With this, the color filter forming process can be simplified in the same manner as in the second embodiment.

Furthermore, although the thin-film 4 is sufficient being a transparent film, a reduction in transmissivity cuts oblique light and is useful in preventing color mixing.

(Manufacturing Method for the Solid-State Image Sensor)

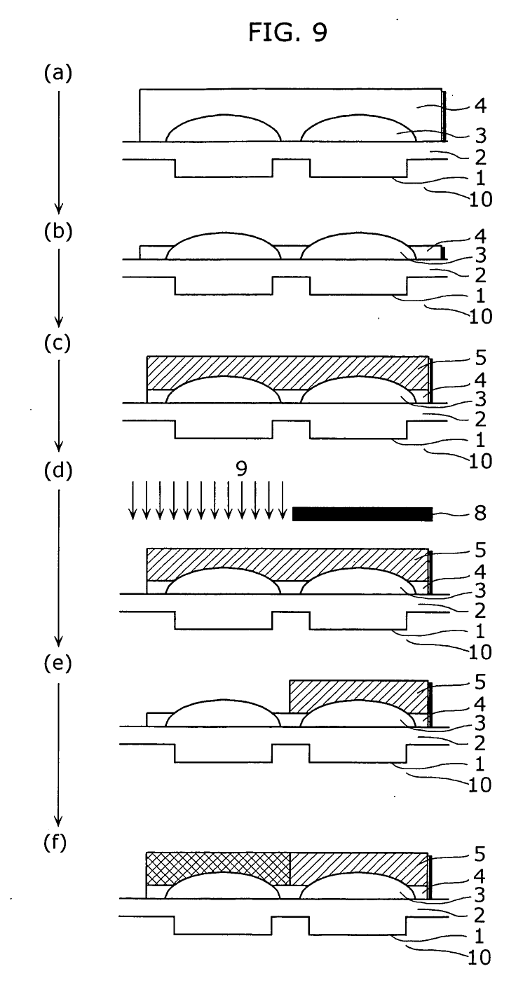

FIG. 9(a) to (f) is a diagram illustrating, in manufacturing sequence, cross-sections of the solid-state image sensor in the present embodiment shown in FIG. 8. Such manufacturing process is explained in (31) to (37) below.

(31) As shown in FIG. 9(a), about 0.5 to 1 μm of an acrylic-like transparent-film is applied on, and in the areas between, each of the in-layer lenses 3. With this, the transparent film is formed higher than the in-layer lens 3.

(32) As shown in FIG. 9(b), a thin-film 4 is formed by etching back the transparent film. In other words, about 0.5 to 1 μm of the thin film 4 is left in place on the areas between the in-layer lenses 3 without leaving the transparent film on the top portion of the surface of the in-layer lenses 3.

(33) As shown in FIG. 9(c), 0.3 to 1.0 μm of a color filter resist 5 is applied on the transparent film 4 and the in-layer lens 3. This process is the same as in (22) mentioned previously.

(34) As shown in FIG. 9(d), exposure is carried out. This process is the same as in (23) mentioned previously.

(35) As shown in FIG. 9(e), development is carried out. This process is the same as in (24) mentioned previously.

(36) As shown in FIG. 9(f), the aforementioned processes (33) to (35) are repeated, and the color filter layer 5 for other colors are respectively formed by patterning. This process is the same as in (25) mentioned previously.

(37) In the same manner as in (26) mentioned previously, a transparent film 6 is formed on the color filter layer 5. With this, the solid-state image sensor having the cross-section shown in FIG. 8 is formed.

Moreover, although the thin-film 4 is sufficient being transparent, having low transmissivity (e.g., black) is also possible. In so doing, the incidence of oblique light is blocked and color mixing can be reduced.

(Variation)

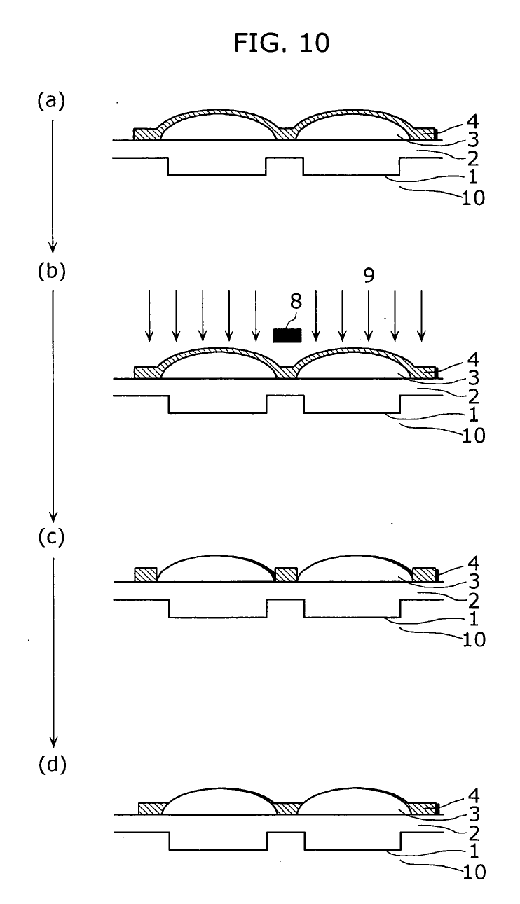

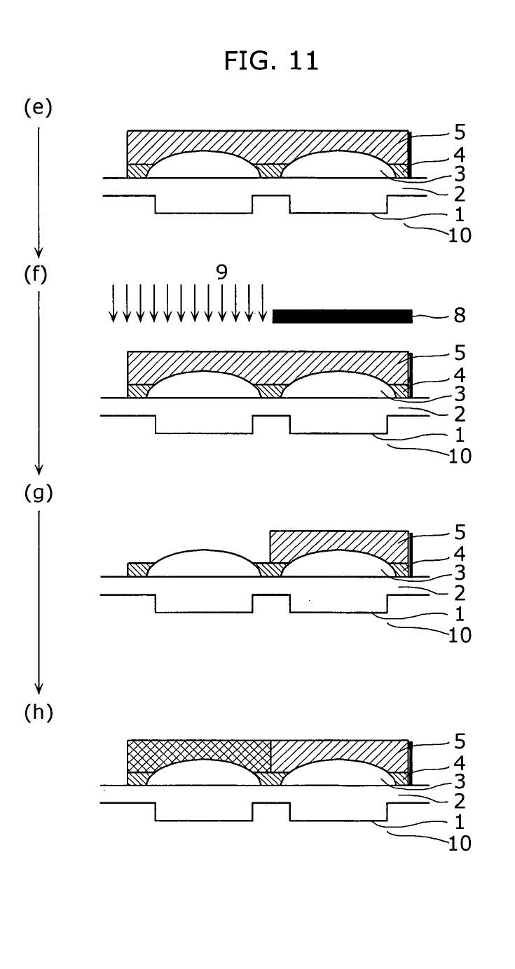

FIG. 10(a) to (d) and FIG. 11(e) to (h) are diagrams illustrating, in manufacturing sequence, cross-sections for a variation on the manufacturing method shown in FIG. 9. Such manufacturing process is explained in (41) to (49) below.

(41) As shown in FIG. 10(a), about 0.1 to 0.9 μm of a transparent resist which can be subjected to patterning is applied on and in the areas between each of the in-layer lenses 3. Phenolic resins and the like, for example, exist among transparent resists that can be subjected to patterning.

(42) As shown in FIG. 10(b), exposure is carried out with the use of a resist mask 8 for leaving the transparent resist in place, on the areas between the in-layer lenses 3.

(43) As shown in FIG. 10(c), a thin-film 4 is formed as a result of leaving the transparent resist in place, on the areas between the in-layer lenses 3 by developing.

(44) As shown in FIG. 10(d), the thin-film 4 is brought into contact with the surface of the bottom portion of the in-layer lens 3 by thermal flow processing. The spectral adjustment explained in the aforementioned process in (32) is possible through the film thickness of this thin-film 4.

(45) As shown in FIG. 11(e), 0.3 to 1.0 μm of a color filter resist 5 is applied on the upper portion of the in-layer lens 3. This process is the same as in (22) mentioned previously.

(46) As shown in FIG. 11(f), exposure is carried out. This process is the same as in (23) mentioned previously.

(47) As shown in FIG. 11(g), development is carried out. This process is the same as in (24) mentioned previously.

(48) As shown in FIG. 11(h), the aforementioned processes (45) to (47) are repeated, and the color filter layer 5 of other colors are respectively formed by patterning. This process is the same as in (25) mentioned previously.

(49) In the same manner as in (26), a transparent film 6 is formed on the color filter layer 5, and in addition, a micro-lens 7 is formed.

The solid-state image sensor having the cross-section shown in FIG. 8 can be manufactured even through a manufacturing method (variation) such as this.

As explained thus far, according to the solid-state image sensor in the present embodiment and the manufacturing method thereof, the adjustment of spectral sensitivity can be made easy, in the same manner as in the second embodiment.

(Fourth Embodiment)

(Structure of the Solid-State Image Sensor)

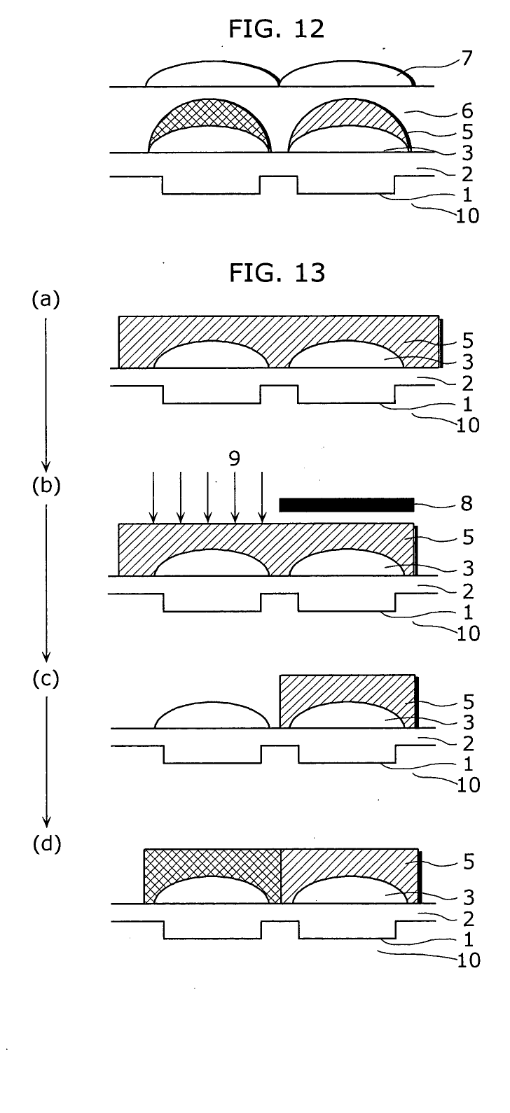

FIG. 12 is a diagram illustrating a cross-section of the solid-state image sensor in the fourth embodiment of the present invention. The structure of the solid state image sensor in the diagram is different, in comparison to the structure shown in FIG. 4 in the first embodiment, in that a color filter layer 5 is formed on top of the in-layer lens. 3 without being present on the areas between the in-layer lenses, and in that the shape of the color filter layer 5 is formed so as to copy the shape of the in-layer lens 3.

The color filter layer 5 is formed only on top of the in-layer lens 3. Consequently, color mixing can be reduced. Furthermore, the shape of the color filter layer 5 is formed to copy the shape of the in-layer lens 3 in order to provide the color filter layer 5 with a lens-effect. As such, improvement of light-collection is facilitated.

(Manufacturing Method for the Solid-State Image Sensor)

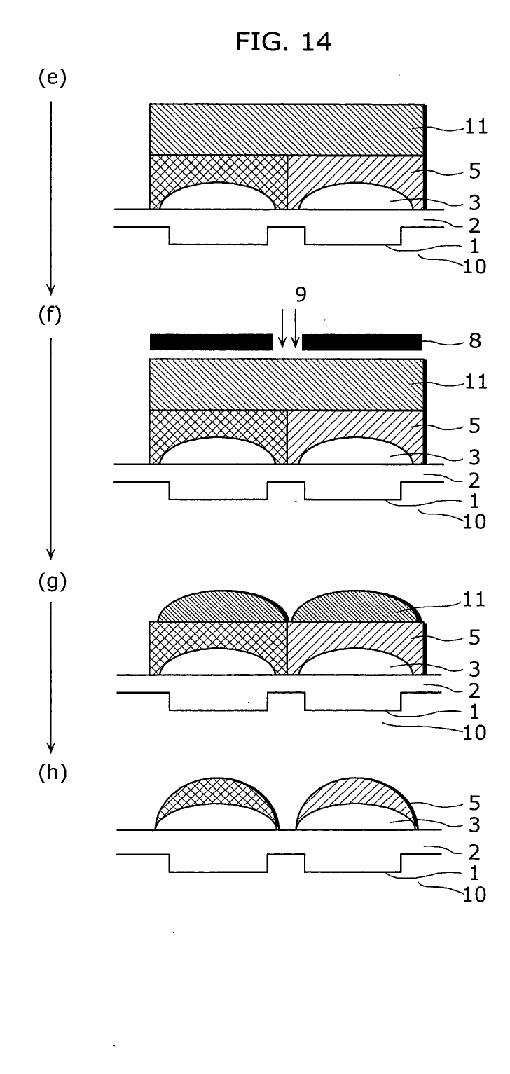

FIG. 13(a) to (d) and FIG. 14(e) to (f) are diagrams illustrating, in manufacturing sequence, cross-sections of the solid-state image sensor in the present embodiment shown in FIG. 12. Such manufacturing process is explained in (51) to (59) below.

(51) As shown in FIG. 13(a), about 0.3 to 1 μm of a color filter resist is applied on an in-layer lens 3. Here, for example, among the 3 colors RGB, the color of the color filter resist 5 is assumed to be R (red).

(52) As shown in FIG. 13(b), a resist mask 8 is placed on the applied color filter resist 5 and exposure is carried out. In the case where the color filter resist 5 is of a positive-type, for example, the resist mask 8 only masks the photodiodes corresponding to the color red, within the predetermined color array (e.g., Bayer Array). It is also possible for the negative-type.

(53) As shown in FIG. 13(c), by developing the exposed color filter resist, a red color filter layer 5 is formed on top of the in-layer lens 3 by leaving the color filter resist in place, above the photodiode 1 corresponding to the color red and removing everything else.

(54) As shown in FIG. 13(d), by repeating the processes in (51) to (53) mentioned previously, the color filter layer 5 for the color blue and the color filter layer 5 for the color green are respectively formed by patterning. With this, the color filter layer 5 for each color is formed in respective positions according to the color array.

(55) As shown in FIG. 14(e), a resist 11 which allows flow processing is applied on the color filter layer 5.

(56) As shown in FIG. 14(f), the portion of the resist 11 that is above the areas between the in-layer lenses 3 is exposed.

(57) As shown in FIG. 14(g), the resist 11 on the portion above the area between the in-layer lenses 3 is removed by developing (that is, the resist on top of the in-layer lens 3 is left in place), and in addition, the shape of the resist is formed into a convex shape (the same shape as the micro-lens).

(58) As shown in FIG. 14(h), the convex shape of the resist 11 is transferred onto the color filter layer 5 by etching back the resist and the color filter layer 5.

(59) As shown in FIG. 12, a transparent film 6 is formed on the color filter layer 5, and in addition, a micro-lens 7 is formed.

Through this manufacturing method, it is possible to manufacture the solid-state image sensor shown in FIG. 12.

As explained thus far, according to the solid-state image sensor in the present embodiment and the manufacturing method thereof, further improvement of light-collection rate can be facilitated as the color filter layer 5 is applied directly on the in-layer lens 3, and in addition, has a lens-shape.

Moreover, in the present embodiment, it is also possible to have a structure with the in-layer lens flat film 4 shown in FIG. 6 in the second embodiment, placed on the insulating film 2 and the in-layer lens 3. It is also possible to have a structure with the in-layer lens flat film 4 shown in FIG. 8 in the third embodiment, placed on the insulating film 2.

Furthermore, in the solid-state image sensors (particularly the solid-state image sensor in which the color filter layer 5 has a lens-effect (FIG. 12)) in the respective embodiments mentioned previously, a structure that is not provided with a top lens (micro-lens 7) is possible. Accordingly, the distance to the photodiode 1 is reduced (i.e., further thin-filming of the solid-state image sensor), and in addition, incidence angle widening is facilitated. In addition, the shortening of manufacturing time (lead time) becomes possible.

Furthermore, although the primary color format which is used in a solid-state image sensor that prioritizes color tone, is explained as an example of the color filter layer 5, it is also possible to have the complementary color scheme which is used in a solid-state image sensor that prioritizes resolution and sensitivity. In the case of the complementary color scheme, a color filter layer for magenta light, a color filter layer for green color light, a color filter layer for yellow color light, and a color filter layer for cyan light are formed on their respective predetermined positions in a commonly known color array, as color filter layers.

Furthermore, although color resists that contain a dye, color resists that contain pigments, and the like, exist as material for forming the color filter layer 5, any of such options is possible. Furthermore, dyeing of a dyeable transparent resist is also possible.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The present invention is suitable as a solid-state image sensor used in a camera, and the like, and is specifically suitable as a built-in camera of a mobile phone, a digital still camera, and a camera unit connected to an information processing device, and the like.

1. A solid-state image sensor comprising:
an in-layer lens for each of a plurality of light-receiving elements formed on a semiconductor substrate; and
a color filter for each of the plurality of light-receiving elements,
wherein the color filter is placed directly on the in-layer lens.

2. The solid-state image sensor according to claim 1, further comprising an inter-lens flat film that forms a flat surface at a position which is lower than an upper portion of the in-layer lens by covering areas between the in-layer lenses and portions of a convex surface of the in-layer lens that are lower than said position.

3. The solid-state image sensor according to claim 2,
wherein an upper surface of the color filter is convex.

4. The solid-state image sensor according to claim 2,
wherein the color filter is placed only on the in-layer lens.

5. The solid-state image sensor according to claim 1,
wherein the color filter is placed only on the in-layer lens.

6. The solid-state image sensor according to claim 1,
wherein an upper surface of the color filter is convex.

7. A solid-state image sensor comprising:
an in-layer lens for each of a plurality of light-receiving elements formed on a semiconductor substrate;
a color filter for each of the plurality of light-receiving elements; and
a transparent thin-film between the color filter and the in-layer lens, formed along a convex surface of the in-layer lens,
wherein the color filter is formed on the transparent thin film.

8. The solid-state image sensor according to claim 7, further comprising an inter-lens flat film that forms a flat surface at a position which is lower than an upper portion of the in-layer lens by covering areas between the in-layer lenses and portions of a convex surface of the in-layer lens that are lower than said position.

9. The solid-state image sensor according to claim 8,
wherein an upper surface of the color filter is convex.

10. The solid-state image sensor according to claim 9,
wherein the color filter is placed only above the in-layer lens.

11. The solid-state image sensor according to claim 7,
wherein the color filter is placed only above the in-layer lens.

12. The solid-state image sensor according to claim 7;
wherein an upper surface of the color filter is convex.

13. A manufacturing method for a solid-state image sensor including an in-layer lens and a color filter for each of a plurality of light-receiving elements formed on a semiconductor substrate, the method comprising:
a first step of applying a resist for a color filter for a first color, on the semiconductor substrate after the in-layer lens is formed;
a second step of exposing the resist using a mask pattern for the color filter for the first color;
a third step of developing the resist so as to leave the color filter for the first color in place, after the exposure; and
a fourth step of performing said application, exposure, and development for color filters for colors aside from the first color.

14. The manufacturing method according to claim 13, comprising a step of forming a transparent thin-film along a convex surface of the in-layer lens prior to the first step,
wherein the resist is formed above the in-layer lens by being applied on the transparent thin-film, in the first and fourth steps.

15. The manufacturing method according to claim 13, further comprising the following steps which are performed prior to the first step:
a step of applying a transparent film on the in-layer lenses and in areas between the in-layer lenses; and
a step of removing, by etch back, the applied transparent film up to a position that is lower than a height of the in-layer lens.

16. The manufacturing method according to claim 13, further comprising the following steps which are performed prior to the first step:
a step of applying a transparent film that can be subjected to patterning, on the in-layer lenses and in areas between the in-layer lenses;
a step of exposing the applied transparent film, using a mask for leaving the transparent film in place in the areas between the in-layer lenses;
a developing step of developing, after exposing, so as to leave the applied transparent film in place only between the in-layer lenses; and
a step of flattening the transparent film so as to cover areas between the in-layer lenses and a surface of a rim of the in-layer lenses through flow processing of the transparent film left in place by developing.

17. The manufacturing method according to claim 13, further comprising the following steps which are performed after the fourth step:
a step of applying a flowable resist on the color filter;
a step of leaving the flowable resist in place on the in-layer lens by developing, and forming the flowable resist that is left in place, into a convex by flow processing; and
a step of forming the color filter into a convex by etching back the flowable resist formed into a convex and the color filter.
